(19) United States
(12) Patent Application Publication
(10) Pub. No.: US 2026/0032929 A1
(43) Pub. Date: Jan. 29, 2026

(54) SEMICONDUCTOR DEVICE AND METHOD OF MANUFACTURING A SEMICONDUCTOR DEVICE THAT FACILITATES TSV TESTING

(71) Applicant: Micron Technology, Inc., Boise, ID (US)

(72) Inventors: Wayne H. Huang, Boise, ID (US); Kyle G. Ross, Boise, ID (US); Somesh M. Nagthan, Boise, ID (US); Eric Kahle, Boise, ID (US)

(21) Appl. No.: 19/276,794

(22) Filed: Jul. 22, 2025

Related U.S. Application Data
(60) Provisional application No. 63/674,621, filed on Jul. 23, 2024.

(51) Int. Cl. H10B 80/00; H01L 23/00; H01L 25/00; H01L 25/065

(52) U.S. Cl. CPC H10B 80/00; H01L 24/08; H01L 25/0657; H01L 25/50; H01L 2224/08145; H01L 2225/06513; H01L 2225/06541; H01L 2225/06596; H01L 2924/1436

(57) ABSTRACT

A stacked semiconductor device and methods for producing the same are disclosed here. A semiconductor device can include a first semiconductor die having a first backside passivation layer and a second semiconductor die having a second backside passivation layer. The first backside passivation layer interfaces to the second backside passivation layer to form a stacked semiconductor assembly and provide one or more communicative couplings between the first and second semiconductor dies. A method of forming a stacked semiconductor assembly includes aligning a first plurality of pads disposed in a first backside passivation layer of a first semiconductor die with a second plurality of pads disposed in a second backside passivation layer of a second semiconductor die. The method further includes bonding the first backside passivation layer to the second backside passivation layer to communicatively couple the first plurality of pads to the second plurality of pads.

### CROSS-REFERENCE TO RELATED APPLICATION(S)

The present application claims priority to U.S. Provisional Patent Application No. 63/674,621, filed Jul. 23, 2024, the disclosure of which is incorporated herein by reference in its entirety.

### TECHNICAL FIELD

The present disclosure is generally related to semiconductor devices and methods for manufacturing the semiconductor devices. In particular, the present technology relates to semiconductor devices incorporating stacked semiconductor assemblies that facilitate testing of through-silicon (or through-substrate) vias (TSVs) during fabrication.

### BACKGROUND

Microelectronic devices, such as memory devices, microprocessors, and other electronics, typically include one or more semiconductor dies mounted to a substrate and encased in a protective covering. The semiconductor dies include functional features, such as memory cells, processor circuits, imager devices, interconnecting circuitry, etc. To meet continual demands on decreasing size, wafers, individual semiconductor dies, and/or active components are typically manufactured in bulk, singulated, and then stacked on a support substrate (e.g., a printed circuit board (PCB) or other suitable substrates). The stacked dies can be communicatively coupled to each other with TSVs. The bulk manufacturing process can increase throughput and reduce difficulties in handling individual semiconductor dies as they continue to shrink in size. The stacked semiconductor dies form a semiconductor assembly that is then incorporated into a semiconductor device such as, for example, high-bandwidth memory (HBM), a system-on-chip (SoC), and/or a system-in-package (SiP).

Functionally testing the semiconductor dies prior to the assembly process can help identify bad semiconductor dies before they are assembled into the stacked semiconductor assembly or the semiconductor device. However, these functional tests may not include testing the integrity of the TSVs either prior to or during the fabrication process as the testing can be complex and time consuming. Accordingly, in related art systems, TSV integrity checks are typically performed after the stacked semiconductor assembly has been fully fabricated and possibly even after the stacked semiconductor assembly has been incorporated into a semiconductor device.

### BRIEF DESCRIPTION OF THE DRAWINGS

FIGS. 1A and 1B illustrate a related art stacked semiconductor assembly fabricated using a hybrid bonding process.

FIG. 1C illustrates testing of TSVs in a related art stacked semiconductor assembly.

FIG. 2A is a cross-sectional view of a stacked semiconductor assembly in accordance with some embodiments of the present disclosure.

FIG. 2B is a cross-sectional top view of the device layers of the semiconductor dies in the stacked semiconductor assembly of FIG. 2A.

FIG. 3 is a cross-sectional view of a stacked semiconductor assembly in accordance with some embodiments of the present disclosure.

FIG. 4A is a cross-sectional view of a stacked semiconductor assembly in accordance with some embodiments of the present disclosure.

FIG. 4B is a cross-sectional view of a semiconductor device incorporating the stacked semiconductor assembly of FIG. 4A.

FIG. 5 is a flow diagram of a process for producing a stacked semiconductor assembly in accordance with some embodiments of the present disclosure.

The drawings have not necessarily been drawn to scale. Similarly, some components and/or operations can be separated into different blocks or combined into a single block for the purpose of discussion of some of the implementations of the present technology. Moreover, while the technology is amenable to various modifications and alternative forms, specific implementations have been shown by way of example in the drawings and are described in detail below. The intention, however, is not to limit the technology to the particular implementations described. On the contrary, the technology is intended to cover all modifications, equivalents, and alternatives falling within the scope of the technology as defined by the appended claims.

### DETAILED DESCRIPTION

Semiconductor devices can include semiconductor memory devices. High data reliability, high speed of memory access, higher data bandwidth, lower power consumption, and reduced chip size are features that are demanded from such semiconductor memory. In recent years, vertically stacked memory devices have been introduced, often referred to as 2.5-dimensional (“2.5D”) memory devices when placed adjacent to a host device or 3-dimensional (“3D”) memory devices when stacked on top of the host device. Some 2.5D and 3D memory devices are formed by stacking memory dies vertically and interconnecting the dies using through-silicon vias (TSVs). The memory dies can be grouped in a “stack” (referred to herein as a “stacked semiconductor assembly”). Benefits of the stacked semiconductor assemblies in the 2.5D and 3D memory devices include shorter interconnects (which reduce circuit delays and power consumption), a large number of vertical vias between layers (which allow wide bandwidth buses between functional blocks in different semiconductor dies), and a considerably smaller footprint. Thus, the stacked memory assemblies in the 2.5 and 3D memory devices contribute to higher memory access speed, lower power consumption, and chip size reduction. Example 2.5D and/or 3D memory devices include Hybrid Memory Cube (HMC) and High Bandwidth Memory (HBM). For example, HBM is a type of memory that includes a vertical stack of dynamic random-access memory (DRAM) dies and an interface die (which, e.g., provides the interface between the DRAM dies of the HBM device and a host device).

A semiconductor device can also include a system-in-package (SiP) configuration, which can integrate one or more HBM devices with a host device (e.g., a graphics processing unit (GPU), computer processing unit (CPU), a tensor processing unit (TCU), and/or any other suitable processing unit) using a base substrate (e.g., a silicon interposer, a substrate of organic material, a substrate of inorganic material and/or any other suitable material that provides interconnection between GPU/CPU and the HBM device and/or provides mechanical support for the components of a SiP device) through which the one or more HBM devices and host communicate. Because traffic between the HBM device and host device resides within the SiP (e.g., using signals routed through the silicon interposer), a higher bandwidth may be achieved between the HBM device and host device than in conventional systems. In other words, the TSVs interconnecting DRAM dies within an HBM device, and the silicon interposer integrating HBM devices and a host device, enable the routing of a greater number of signals (e.g., wider data buses) than is typically found between packaged memory devices and a host device (e.g., through a printed circuit board (PCB)). The high bandwidth interface within a SiP enables large amounts of data to move quickly between the host device (e.g., GPU/CPU/TCU, etc.) and HBM devices during operation. For example, the high bandwidth channels can be on the order of 1000 gigabytes per second (GB/s, sometimes also referred to as gigabits (Gb)). As a result, the SiP device can quickly complete computing operations once data is loaded into the one or more HBM devices. SiP devices, in turn, are typically integrated with a package substrate (e.g., a PCB) adjacent to other electronics and/or other SiP devices within a packaged system. It will be appreciated that such high bandwidth data transfer between the host device and the memory of HBM devices can be advantageous in various high-performance computing applications, such as video rendering, high-resolution graphics applications, artificial intelligence and/or machine learning (AI/ML) computing systems and other complex computational systems, and/or various other computing applications.

Traditionally, the circuits in semiconductor dies (e.g., DRAM dies) are functionally tested at the wafer stage to determine known good dies, and only the known good dies are used in fabricating a semiconductor device (e.g., SiP, HBM, etc.). However, as discussed above, the TSVs in the semiconductor dies may not be checked until after the stacked semiconductor assembly has been fabricated. Although there may be some built-in redundancy with respect to the number of TSVs, waiting until the stacking process is complete to check TSV integrity can be risky as the semiconductor device may need to be discarded if too many TSVs fail the integrity tests. This risk is heightened when manufacturing stacked semiconductor assemblies having 8, 12, or more semiconductor dies in each stacked semiconductor assembly. TSV failures within a single semiconductor die could mean that the entire stacked semiconductor assembly and possibly even the semiconductor device has to be discarded. Accordingly, it is desirable have stacked semiconductor assemblies that allow for testing of TSV integrity and circuits throughout the fabrication process so that a semiconductor die with failed TSVs can be identified before the stacked semiconductor assembly has been fully assembled and/or incorporated into a semiconductor device.

Semiconductor devices with stacked semiconductor assemblies, and methods for their manufacture, are disclosed herein. The stacked semiconductor assemblies can be configured so as to facilitate testing of TSV integrity and/or functional checks of circuits throughout the fabrication process. In some embodiments, the stacked semiconductor assembly includes a plurality of semiconductor dies with each die having a frontside passivation layer and a backside passivation layer. Each of the frontside and backside passivation layers can have one or more conductive features disposed therein (e.g., bond pads, exposed interconnects, thermal transfer units, and/or various other conductive features). In addition, the frontside passivation layer can include a frontside bonding surface, and the backside passivation layer can include a backside bonding surface. The frontside and/or backside bonding surfaces can be used for bonding with other dies (e.g., another semiconductor die, an interface or base die, etc.) In some embodiments, the stacked semiconductor assembly can include a plurality of dies, which can be arranged such that a backside bonding surface of one or more semiconductor dies of the plurality of semiconductor dies respectively bonds with a backside bonding surface of one or more other semiconductor dies of the plurality of semiconductor dies (referred to herein as “backside bonding”). The backside bonding can be performed via, for example, hybrid bonding, solder bonding or some other type of bonding. In some embodiments, the backside bonding communicatively couples the semiconductor dies via the conductive features (e.g., bond pads, also referred to herein as “pads”) disposed in the respective backside passivation layers.

In some embodiments, a first semiconductor sub-assembly having a pair of backside bonded semiconductor dies can be bonded to a second semiconductor sub-assembly having a pair of backside bonded semiconductor dies. For example, a frontside bonding surface of a semiconductor die in the first sub-assembly can be bonded (e.g., via bonding, solder bonding, etc.) to a frontside bonding surface of a semiconductor die in the second sub-assembly. Bonding between two frontside bonding surfaces is also referred to herein as “frontside bonding.” In some embodiments, the frontside bonding communicatively couples the first and second pairs of backside bonded semiconductor dies via conductive features (e.g., bond pads) disposed in the respective frontside passivation layers. In some embodiments, the frontside bonding can be a solder bond such as, for example, a SnAg (tin-silver) solder bond. In other embodiments, the frontside bonding can be a hybrid bond. As used herein, “frontside” means the portion of the semiconductor die proximate to the device layer and on a same side of the substrate as the device layer, and “backside” means the portion of the semiconductor die that is remote from the device layer and on an opposite side of the substrate as the device layer.

In some embodiments, a method of forming a stacked semiconductor assembly includes aligning a first plurality of pads disposed in a first backside passivation layer of a first semiconductor die with a second plurality of pads disposed in a second backside passivation layer of a second semiconductor die. The method further includes bonding a first backside bonding surface of the first backside passivation layer to a second backside bonding surface of the second backside passivation layer such that the first plurality of pads is communicatively coupled to the second plurality of pads after the bonding.

For case of reference, semiconductor dies and/or stacked semiconductor assemblies may be described herein with reference to outer and inner, top and bottom, upper and lower, upwards and downwards, and/or horizontal plane, x-y plane, vertical, or z-direction relative to the spatial orientation of the embodiments shown in the figures. It is to be understood, however, that the stacked semiconductor assembly, and the surfaces bonded therein, can be moved to, and used in, different spatial orientations without changing the structure and/or function of the disclosed embodiments of the present technology. In addition, the scope of the present disclosure is not confined to any subset of embodiments and is confined only by the limitations set out in the appended claims.

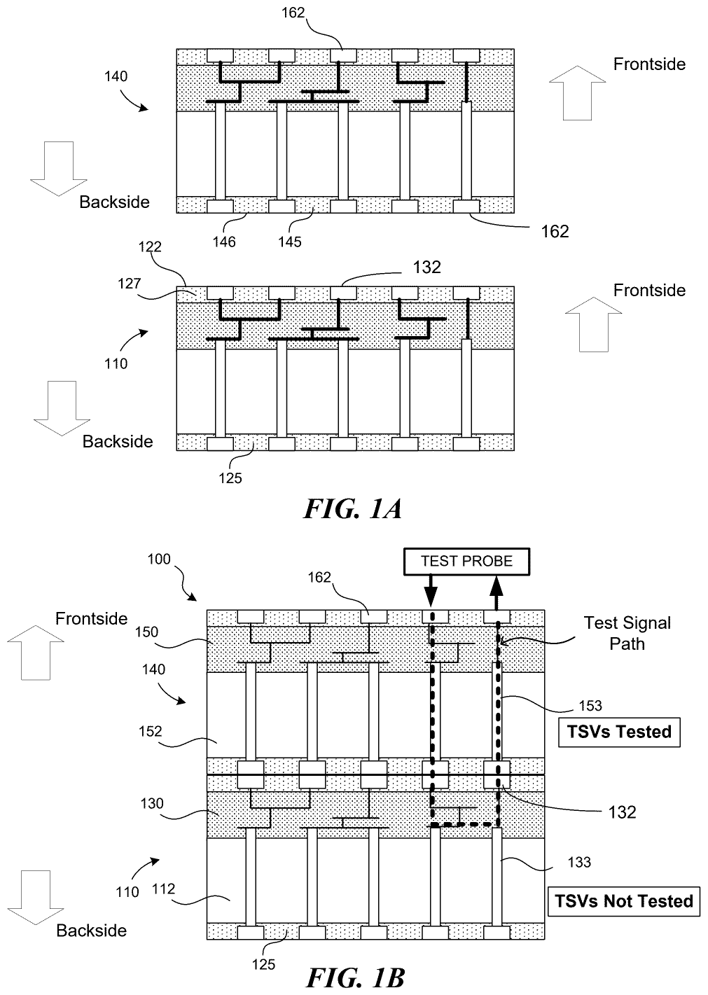

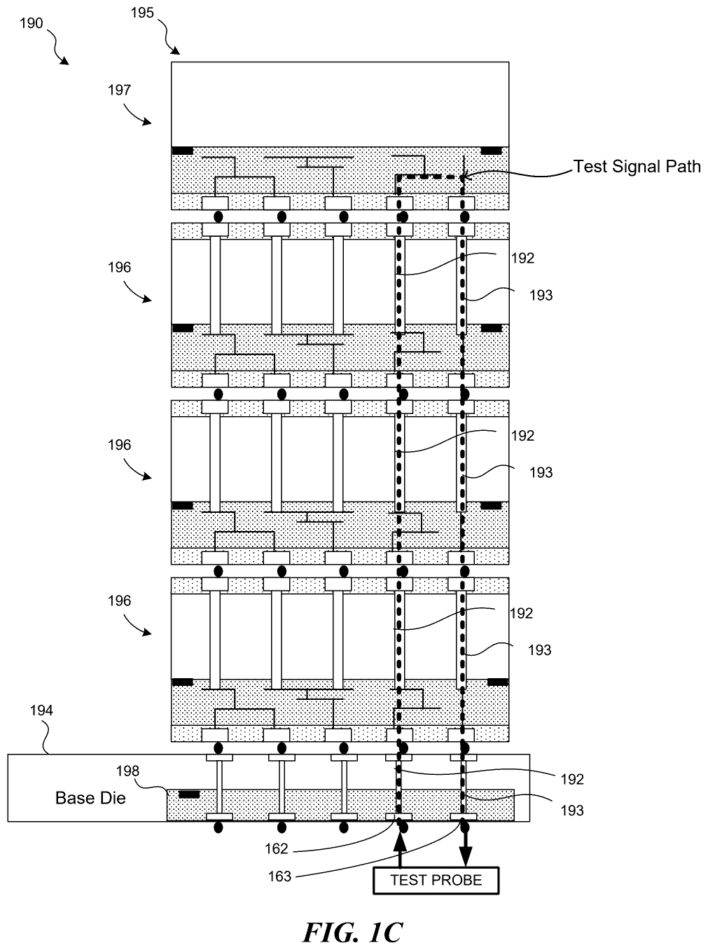

FIGS. 1A and 1B illustrate a related art method of assembling a stacked semiconductor assembly 100. FIG. 1A illustrates individual semiconductor dies 110 and 140 prior to the bonding and FIG. 1B illustrates the stacked semiconductor assembly 100 after semiconductor dies 110 and 140 have been bonded. The bonding process communicatively couples semiconductor die 110 and semiconductor die 140. As seen in FIG. 1B, the semiconductor assembly 100 is stacked using a related art fabrication process in which the frontside bonding surface 122 of frontside bonding layer 127 of semiconductor die 110 is bonded to the backside bonding surface 146 of backside bonding layer 145 of semiconductor die 140 (referred to herein as “frontside/backside bonding”). The semiconductor dies include built-in test circuits, which are located in the device layer of the stacked semiconductor die for functionally checking components (e.g., circuits) of the semiconductor die prior to assembly. However, while it could be possible for the built-in test circuits to create a test signal path for testing some of the TSVs during fabrication of the stacked semiconductor assembly, the TSVs in the bottom end semiconductor die of the stacked semiconductor assembly cannot be tested during fabrication using the standard test equipment. This is because the standard test equipment is positioned on the top end semiconductor die of the stacked semiconductor assembly and the TSVs in the bottom end semiconductor die cannot be accessed for testing using the built-in test circuitry.

For example, as seen in FIG. 1B, a test signal path for checking the TSVs cannot be created between any of the conductive pads 162 that can check the TSVs 133 in semiconductor die 110 (e.g., via conductive pads 132). This is because semiconductor die 110 does not include built-in test circuits at the backside of the semiconductor die to permit access to TSVs 133. That is, there are no built-in test circuits on the backside of semiconductor die 110 between the substrate 112 and the backside bonding layer 125 to route the test signal path. Similarly, there are no built-in test circuits on the backside of semiconductor die 140 between the substrate 152 and the backside bonding layer 145. Any built-in test circuits are only in the device layers 130, 150 of the semiconductor dies 110, 140. Accordingly, as seen in FIG. 1B, if a test signal path (dotted line) could be created, the path only includes TSVs 153 of semiconductor die 140. Because the TSVs in the bottom end semiconductor die cannot be tested during fabrication of the stacked semiconductor assembly, for related art semiconductor assemblies, the integrity testing of the TSVs is typically delayed until after the completed semiconductor assembly is coupled to an interface (or base) die as shown in FIG. 1C.

FIG. 1C illustrates the testing of TSVs in a related art stacked semiconductor assembly 195 configured using frontside/backside bonding using solder bonding. The semiconductor assembly 195 includes semiconductor dies 196, which can be similar to semiconductor die 110 discussed above, and a topmost semiconductor die 197, which is functionally equivalent to semiconductor dies 196 but may not include TSVs in some cases. The stacked semiconductor assembly 195 can be stacked on an base die 194 of a semiconductor device 190 that includes logic/control circuits (e.g., memory control circuits) and/or interconnections (not shown) in device layer 198. As seen in FIG. 1C, built-in test circuits in the device layer 198 of base die 194 and in the device layers of semiconductor dies 196 can be configured such that TSVs 192 and pad 162 are connected in series and the TSVs 193 and pad 163 are connected in series. In addition, the TSVs 192 can be communicatively connected (daisy chained) to TSVs 193 by a built-in circuit in the topmost semiconductor die 197 to create a test signal path (dotted line) that extends from pad 162 to pad 163 of base die 194 and includes the four sets of TSVs 192 and 193 (one set in base die 194 and three sets in the semiconductor dies 196 of stacked semiconductor assembly 195). As seen in FIG. 1C, because the stacked semiconductor assembly 195 must first be completed and assembled on the base die 194 before the TSVs can be tested using the Test Probe, a failed TSV test could result in the stacked semiconductor assembly 195 and possibly even the semiconductor device 190 being discarded.

In embodiments of the present disclosure, a semiconductor assembly is stacked such that at least one of the stacked semiconductor dies is “flipped” in comparison to the other die or dies in the semiconductor assembly. The flipped semiconductor die can be positioned relative to another semiconductor die in the semiconductor assembly such that pads on a backside bonding surface of the flipped semiconductor die align with pads on a backside bonding surface of the other semiconductor die. The flipped semiconductor die and the other semiconductor die can be bonded via backside bonding to form the stacked semiconductor assembly. That is, the flipped semiconductor die can be arranged so as to create a backside surface to backside surface bond (e.g., a hybrid bond, a solder bond, etc.) with the other semiconductor die in the stack. Once bonded, the pads on the flipped semiconductor die communicatively couple with the pads on the other semiconductor die.

In some embodiments, the bonds between semiconductor dies can include a hybrid bond. Hybrid bonding, sometimes called fusion bonding or direct bonding, describes a bonding process without any additional intermediate layers between the dies. Hybrid bonding processes rely on chemical bonds and interactions between two surfaces. For example, a hybrid bonding process for silicon is based on intermolecular interactions including van der Waals forces, hydrogen bonds, and strong covalent bonds. In hybrid bonding, bonding layers (e.g., passivation layers, which typically consist of a dielectric material (e.g., silicon oxide, SiOx) and embedded pads (e.g., conductive pads—Cu or another appropriate metal or alloy)) are formed on each of the semiconductor dies. After the bonding layers are formed, the semiconductor dies are aligned to ensure accurate positioning of the bonding areas and/or the embedded pads, and the semiconductor dies are then brought into contact to begin the bonding process. The embedded pads form interconnections between the semiconductor dies that communicatively couple the pads. After bonding, the semiconductor dies undergo thermal annealing such that the silicon oxide layer in the dielectric material undergoes viscous flow, which closes any gaps to strengthen and enhance the hybrid bond. The hybrid bonding process is known to those skilled in the art and thus, for brevity, will not be discussed further.

In some embodiments, the bonds between semiconductor dies can include a solder bond. For example, solder bumps (or solder balls) (e.g., Cu, SnAg, or another appropriate metal or alloy) can be placed on the pads in a passivation layer of the semiconductor die. After placement, the solder bumps on the semiconductor die can be aligned with pads in a passivation layer on the other semiconductor die. The solder bumps can be heated to establish a re-flow to create the bond between and interconnect the two semiconductor dies that communicatively couple the pads. The solder bonding process is known to known to those skilled the art and thus, for brevity, will not be discussed further.

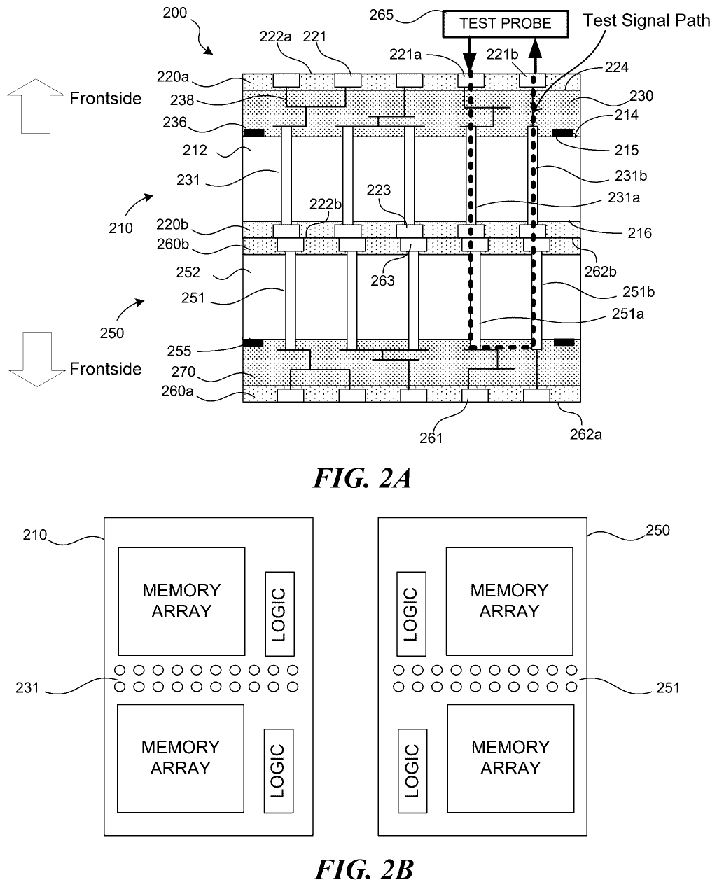

FIG. 2A illustrates a stacked semiconductor assembly 200 with a stacking arrangement that is consistent with some embodiments of the present disclosure. The stacked semiconductor assembly 200 includes two semiconductor dies 210 and 250. The semiconductor die 210 can include a semiconductor substrate 212 (e.g., silicon) that has an upper surface 214 and a lower surface 216 opposite the upper surface 214. A device layer 230 (shaded region) can be deposited on the upper surface 214 of the substrate 212. The device layer 230 can include the logic and/or memory circuits 236 along with associated metal layers 238 for the semiconductor die 210. The device layer 230 can also include built-in test circuits 215 to be used in performing functional checks on the logic and/or memory circuits and/or integrity checks on the TSVs such as TSVs 231a and 231b (collectively TSVs 231). A frontside passivation layer 220a can be deposited on the surface 224 of the device layer 230 and can have a frontside bonding surface 222a facing outwardly from the device layer 230. The frontside passivation layer 220a can be embedded with pads 221 and/or other conductive features (e.g., exposed interconnects, thermal transfer units, etc.) disposed therein. The pads 221 provide for communicative couplings between the components (e.g., circuits) in the device layer 230 (via, e.g., the metal layers 238) and other semiconductor dies and/or external devices.

A backside passivation layer 220b can be deposited on the surface 216 of the substrate and can have a backside bonding surface 222b facing outwardly from the substrate 212. The backside passivation layer 220b can be embedded with pads 223 and/or other conductive features (e.g., exposed interconnects, thermal transfer units, etc.) disposed therein. The pads 223 provide for communicative couplings between the components (e.g., circuits) in the device layer 230 (via the TSVs 231 and/or the metal layers 238) and other semiconductor dies and/or external devices. The functional features of semiconductor die 250 are similar to semiconductor die 210 and thus, for clarity and brevity, will not be repeated.

The passivation layers 220a,b and 260a,b insulate the respective semiconductor dies 210, 250 and, depending on the arrangement, facilitate bonding between the semiconductor die 210, 250 and other dies (e.g., via bonding surfaces 222a, 222b, 262a, 262b). For example, in FIG. 2A, the backside passivation layer 220b of semiconductor die 210 and backside passivation layer 260b of semiconductor die 250 facilitate bonding between the semiconductor dies 210 and 250. The passivation layers 220a,b in semiconductor die 210 and the passivation layers 260a,b in semiconductor die 250 can be composed of a dielectric material, a polymer material, and/or various other suitable materials. Examples of dielectrics that can be used include silicon dioxide, silicon nitride, silicon oxynitride, silicon carbon nitride, polysilicon, silicon carbonate, and/or any other suitable dielectric. Examples of polymers include polypyrrole, polyaniline, polydopamine, and/or various suitable epoxy resins.

As illustrated in FIG. 2A, semiconductor die 250 in the stacked semiconductor assembly 200 is flipped in comparison to semiconductor die 210 (e.g., frontside of semiconductor die 250 is facing down and the frontside of semiconductor die 210 is facing up) such that the semiconductor die 250 can be backside bonded to semiconductor die 210. That is, a backside bonding surface 262b of backside passivation layer 260b can interface with (e.g., by direct contact) the backside bonding surface 222b of backside passivation layer 220b. In some embodiments, the interface between the backside passivation layers 220b and 260b can be a bonded interface (e.g., hybrid bonding, solder bonding, etc.). The bond between surfaces 222b and 262b helps allow semiconductor die manufacturers meet demands for reduction in the volume occupied by stacked die assemblies. In some embodiments, the backside passivation layers 220b and 260b can include pads 223, 263 that communicatively couple semiconductor dies 210 and 250 via the respective TSVs 231, 251 (TSVs 231a, 231b, 251a, and 251b are labeled in FIG. 2A) when bonded. In other embodiments, the communicative couplings between the semiconductor dies 210 and 250 can be formed by a solder bond process in which the pads 223 and 263 are bonded using, for example, micro-bump technology (e.g., using copper micro-bumps). Regardless of the type of bond used, the communicative couplings of the pads 223, 263 allow for power, control, command, and/or address signals to be transmitted between the logic and/or memory circuits in the device layers 230, 270 of the respective semiconductor dies 210, 250. The pads 221, 261 in the frontside passivation layers 220a and 260a can provide communicative couplings to other stacked semiconductor dies, an interface die in a semiconductor device (e.g., an HBM device), and/or external devices.

In some embodiments, the TSVs 231, 251 can be made from copper, nickel, tungsten, cobalt, indium, tin, ruthenium, molybdenum, bismuth, aluminum, polysilicon and/or polycide (e.g., tungsten silicon, molybdenum silicon, nickel silicon, etc.), conductor-filled epoxy, and/or other suitable electrically conductive materials. The TSVs 231, 251 can be surrounded by an insulator to electrically isolate the TSVs 231, 251 from the substrate 212, 252. In some embodiments, the pads 221, 223, 261, 263 can be made from copper, nickel, tungsten, cobalt, indium, tin, ruthenium, molybdenum, bismuth, aluminum, polysilicon and/or polycide (e.g., tungsten silicon, molybdenum silicon, nickel silicon, etc.), conductor-filled epoxy, and/or other suitable electrically conductive materials. In some embodiments, the TSVs 231, 251 and the pads, 221, 223, 261, 263 can be made from the same material (e.g., when a pad is a continuation of the TSV). For example, the TSVs 231, 251 and the pads 221, 223, 261, 263 can both be made from copper. In other embodiments, the TSVs 231, 251 and pads 221, 223, 261, 263 can be made from differing materials. For example, the TSVs 231, 251 can be made from nickel while the pads 221, 223, 261, 263 can be made from copper. In some such embodiments, the TSVs 231, 251 and pads 221, 223, 261, 263 can be formed in a single step. In other embodiments, they can be formed in separate steps.

In frontside/backside bonding between semiconductor dies such as that shown in FIGS. 1B and 1C, the component layouts of the semiconductor dies in the stacked semiconductor assembly can be substantially identical. That is, the semiconductor dies have the same arrangement of components (e.g., circuits) so that, when stacked using frontside/backside bonding, the components in the respective semiconductor dies will be properly aligned to each other and to the interconnecting TSVs. In contrast, for backside bonding, the components in the flipped semiconductor die will not be in alignment to the other semiconductor dies if all the stacked semiconductor dies have substantially identical component layouts. Accordingly, when using backside bonding, the layout of the logic circuits and/or the routing of the metal layers in the flipped semiconductor die may need to be rearranged in order to properly align the connections and components of the flipped semiconductor die with those of the other semiconductor die or dies.

In some embodiments, the layout of components (e.g., circuits and/or metal layers) in the device layer of a flipped semiconductor die can be substantially a “mirror image” of the layout of components in the non-flipped semiconductor die. For example, FIG. 2B illustrates top cross-sectional views showing simplified exemplary layouts of components in the device layers 230, 270 of semiconductors dies 210 and 250, respectively. The semiconductor dies 210, 250 can be memory devices such as, for example DRAM dies. Each semiconductor die 210, 250 can include memory arrays and corresponding logic circuits. In addition, each semiconductor die 210, 250 can respectively include one or more TSVs 231, 251, which provide the interconnection to the pads 221, 223, 261, 263 and the other semiconductor dies as discussed above.

As seen in FIG. 2B, the layout of components in semiconductor die 250 are a mirror image of the layout of components in semiconductor die 210. Accordingly, when semiconductor die 250 is flipped and stacked onto semiconductor assembly 200, the components and connections, including the TSV connections, in semiconductor die 250 will align with the components and connections in semiconductor die 210. In some embodiments, some or all of the components in semiconductor die 250 may not have a mirrored layout. In such cases, the metal layers can be rerouted so that the TSVs and the logic and/or memory circuits are connected appropriately. Accordingly, by rearranging components (e.g., a mirrored arrangement) and/or rerouting metal layers appropriately, the semiconductor die 210 and semiconductor die 250 can be communicatively coupled using backside bonding.

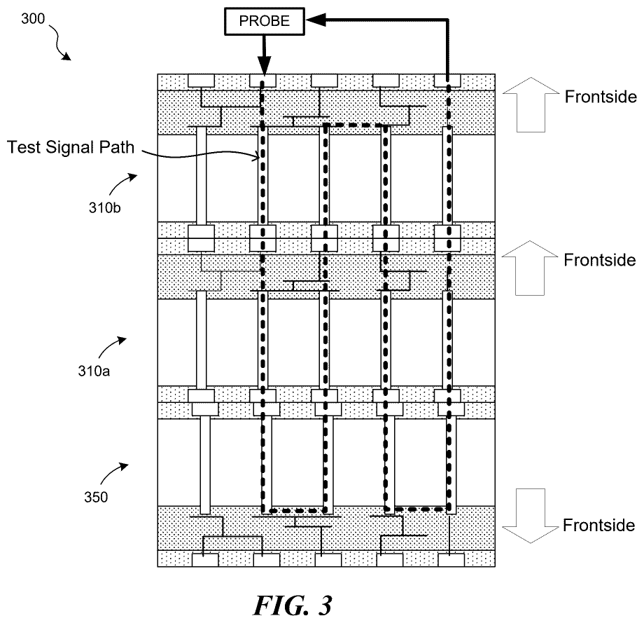

In contrast to related art assemblies in which the TSVs in the bottom end of the semiconductor assembly cannot be accessed for testing, the backside bonding using a flipped semiconductor die allows for the TSVs in all the semiconductor dies in the stacked semiconductor assembly to be tested during the fabrication of the stacked semiconductor assembly. In the embodiment of FIG. 2A, the TSVs 231, 251 in semiconductor dies 210, 250 can be tested during fabrication of the stacked semiconductor assembly 200. That is, the TSV testing need not wait until the semiconductor assembly 200 is bonded to, for example, an interface die, as in related art assemblies. For example, in some embodiments, the TSVs 251 in flipped semiconductor die 250 can be tested prior to the backside bonding with semiconductor die 210. Once the semiconductor dies 210 and 250 are backside bonded (e.g., hybrid bonding, solder bonding, etc.), some or all of the TSVs 231, 251 in both semiconductor dies 210 and 250 can be tested to ensure that TSVs 231 and 251 are good. For example, to check TSVs 231a, 231b, 251a, and 251b, a test signal path (dotted line) can be created between pads 221a and 221b by built-in test circuits 215 and 255 in the device layers 230, 270 of the stacked semiconductor assembly 200. If needed (e.g., if the existing metal layers 238 do not already communicatively couple the pads to the TSVs), built-in test circuit 215 in device layer 230 of semiconductor die 210 can be configured to provide the communicative coupling between the pads 221a and 221b to TSVs 231a and 231b, respectively. Further, built-in test circuit 255 in device layer 270 of semiconductor die 250 can be configured to communicatively couple (daisy chain) TSV 251a to TSV 251b in semiconductor die 250. The test signal path that is created between pads 221a and 221b allows TSVs 231a, 251a, 251b, and 231b to be tested at the same time. Similar test signal paths can be created to test the other TSVs 231, 251 in semiconductor dies 210, 250. In the embodiment of FIG. 2A, a column of TSVs containing TSVs 231a and 251a is daisy chained to a column of TSVs containing TSVs 251b and 231b for testing. In other embodiments, the test signal path created by the built-in test circuits can include more than two TSV columns (e.g., see FIG. 3). By checking the integrity of the TSVs throughout the fabrication of the stacked semiconductor assembly, a partially-fabricated stacked semiconductor assembly with defective TSVs can be discarded before more known good dies are added to the assembly and/or before the assembly is bonded to a semiconductor device.

Once a test signal path has been created by the built-in test circuits, a test probe can be used to perform, for example, electrical checks on the TSVs and related structures. For example, as seen in FIG. 2A, a test signal path (dotted line) extends form pad 221a to 221b. By placing test probe 265 on pads 221a and 221b, the integrity of TSVs 231a, 251a, 251b, and 231b in both semiconductor dies 210 and 250 can be tested at the same time. In some embodiments, the TSV integrity checks include resistance checks of the TSV chain, capacitance checks of the TSV chain, test current readouts, and/or other electrical checks, to determine whether there is a short in the TSV chain, an open in the TSV chain, excessive current leakage in the TSV chain, cracks in the semiconductor dies of the stacked semiconductor assembly, etc. In addition, in some embodiments, along with performing TSV integrity checks, functional checks of logic and/or memory circuits can be performed during to the stacking process to ensure the logic and/or memory circuits have not been damaged while stacking the semiconductor dies. In some embodiments, to save assembly time and resources, the initial functional tests on the semiconductor dies to determine known good dies can be skipped and both the functional checks on the circuitry and the TSV integrity checks can be performed during fabrication of the stacked semiconductor assembly. Test probes are known in the art and thus, for brevity, are not discussed further.

In the embodiment of FIG. 2A, the stacked semiconductor assembly includes two semiconductor dies. However, in other embodiments, the stacked semiconductor assembly can include three or more semiconductor dies such as, for example, 4, 8, 12, or more semiconductor dies. FIG. 3 illustrates a stacked semiconductor assembly 300 with three semiconductor dies 310a, 310b, and 350. The semiconductor dies 310a and 310b can have a configuration similar to that of semiconductor die 210 of FIGS. 2A and 2B and semiconductor die 350 can have a configuration similar to that of semiconductor die 250 of FIGS. 2A and 2B. Semiconductor dies 350 and 310a can be bonded (e.g., via hybrid bonding, solder bonding, etc.) using a backside bonding process as discussed above, and semiconductor dies 310a and 310b can be bonded (e.g., via hybrid bonding, solder bonding, etc.) using a frontside/backside bonding process as discussed above. A stacked semiconductor assembly can have any number of semiconductor dies so long as an end semiconductor die in the stacked semiconductor assembly is flipped (e.g., similar to semiconductor die 350) in comparison to the other semiconductor dies in the stacked semiconductor assembly. For example, any number of semiconductor dies can be stacked on semiconductor die 310b using frontside/backside bonding so long as flipped semiconductor die 350 is at an end of the semiconductor assembly and backside bonded to the adjacent semiconductor die.

In the embodiments of FIG. 2A, two columns of TSVs were daisy chained together to form the test signal path. However, the TSV integrity checks are not limited to TSVs located in two columns. As seen in FIG. 3, the test signal path in this embodiment includes four TSV columns that are daisy chained together to form the test signal path (dotted line). In other embodiments, more than four or less than four TSV columns can be daisy chained together to form the test signal path.

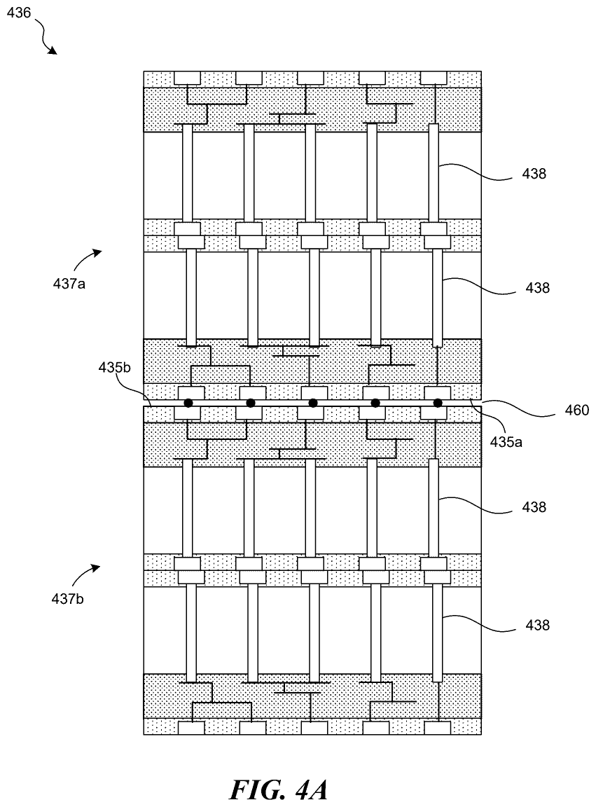

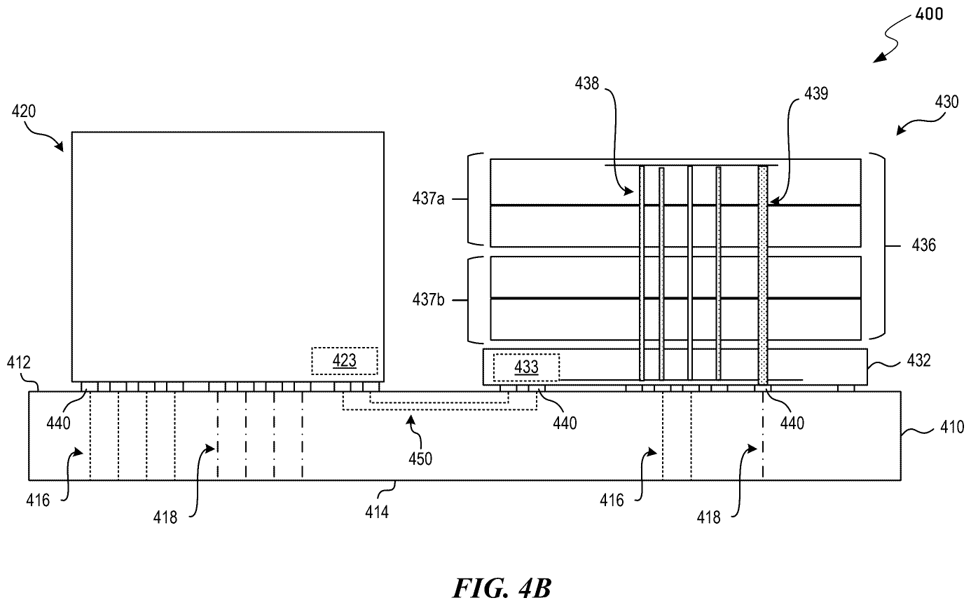

FIG. 4A illustrates another stacked semiconductor assembly that is consistent with the present disclosure. As seen in FIG. 4A, the stacked semiconductor assembly 436 is composed of multiple stacked semiconductor sub-assemblies (e.g., stacked semiconductor sub-assemblies 437a, 437b). Each of the configuration of stacked semiconductor sub-assemblies 437a, 437b can be consistent with embodiments of the present disclosure. For example, each stacked semiconductor sub-assembly 437a, 437b can be configured similar to stacked semiconductor assembly 200. In other embodiments, the configuration of the sub-assemblies in stacked semiconductor assembly 436 can be similar to stacked semiconductor assembly 300. In still other embodiments, the stacked semiconductor assembly 436 can include any combination of sub-assemblies configured as stacked semiconductor assembly 200, stacked semiconductor assembly 300, and/or another configuration consistent with the present disclosure.

As seen in FIG. 4A, the sub-assemblies 437a,b are bonded to each other using frontside/frontside bonding (e.g., hybrid bonding, solder bonding, etc.). That is, a frontside bonding surface 435a of a semiconductor die in sub-assembly 437a is bonded to a frontside bonding surface 435b of a semiconductor die in sub-assembly 437b. In the embodiment of FIG. 4A, the sub-assemblies 437a and 437b are bonded using solder bonding at interface 460. However, in other embodiments, interface 460 can be a hybrid bond. Although the embodiment of FIG. 4A is shown with two stacked semiconductor assemblies, in other embodiments, any number of stacked semiconductor sub-assemblies can be frontside/frontside bonded to each other.

During fabrication of each sub-assembly and/or during the stacking of each sub-assembly onto the stacked semiconductor assembly 436, the TSVs in each semiconductor die can be tested as discussed above. That is, the built-in test circuits in the appropriate device layers can create a test signal path that includes two or more TSV columns that are daisy chained together as discussed above. Any failed sub-assemblies 437a, 437b can be discarded prior to stacking them onto stacked semiconductor assembly 436 and/or any failed stacked semiconductor assemblies 436 can be discarded prior to bonding the stacked semiconductor assembly 436 onto a semiconductor device.

FIG. 4B illustrates a stacked semiconductor assembly bonded to a semiconductor device 400. FIG. 4B is a partially schematic cross-sectional diagram of a SiP device 400 that includes an HBM device 430. The HBM device 430 includes a stacked semiconductor assembly 436 of FIG. 4A. As illustrated in FIG. 4B, the SiP device 400 includes a base substrate 410 (e.g., a silicon interposer, another organic interposer, an inorganic interposer, and/or any other suitable base substrate), as well as a host device 420 and an the HBM device 430 each integrated with (e.g., carried by and coupled to) an upper surface 412 of the base substrate 410 through a plurality of interconnect structures 440 (three labeled in FIG. 4B). The interconnect structures 440 can be solder bonds (e.g., solder balls), metal-metal bonds, and/or any other suitable conductive structure that mechanically and electrically couples the base substrate 410 to each of the host device 420 and the HBM device 430. Further, the host device 420 is coupled to the HBM device 430 through one or more communication channels 450 formed in the base substrate 410. The communication channels 450 can include one or more route lines (two illustrated schematically in FIG. 4B) formed into (or on) the base substrate 410.

As further illustrated in FIG. 4B, the base substrate 410 includes a plurality of external signal TSVs 416 and a plurality of external power TSVs 418 extending between the upper surface 412 and a lower surface 414 of the base substrate 410. The external signal TSVs 416 can communicate signals (e.g., data, control signals, processing commands, and/or the like) between the host device 420 and/or the HBM device 430 and an external component (e.g., a PCB the base substrate 410 is integrated with, an external controller, and/or the like). The external power TSVs 418 provide electrical power to the host device 420 and/or the HBM device 430 from an external power source.

In the illustrated environment, the host device 420 can include a variety of components, such as a processing unit (e.g., CPU/GPU/TCU, etc.), one or more registers, one or more cache memories, and/or a variety of other components. For example, in the illustrated environment, the host device 420 includes a host IO circuit 423 that can direct signals to and/or from the HBM device 430 through the communication channels 450. Additionally, or alternatively, the host IO circuit 423 can direct signals to and/or from an external component (e.g., a controller coupled to one or more of the external signal TSVs 416 and/or the like).

The HBM device 430 can include an interface (or base) die 432 and a stacked semiconductor assembly 436 with semiconductor sub-assemblies 437a,b (see FIG. 4A) carried by the interface die 432. Each of the semiconductor dies in the stacked semiconductor assembly 436 can be a DRAM die. The HBM device 430 also includes one or more signal TSVs 438 (four illustrated in FIG. 4B) and one or more power TSVs 439 (one illustrated in FIG. 4B) each extending from the interface die 432 to the top of sub-assembly 437a. The power TSV(s) 439 provide power (e.g., received from one or more of the external power TSVs 418) to the interface die 432 and the stacked semiconductor assembly 436. The signal TSVs 438, which include TSVs for carrying control, address, and DQ signals, communicably couple the stacked semiconductor assembly 436 to a HBM memory controller circuit 433 in the interface die 432 (in addition to various other circuits in the interface die 432). In turn, the HBM memory controller circuit 433 can direct DQ, control, and/or address signals to and/or from the host device 420 and/or an external component (e.g., an external storage device coupled to one or more of the external signal TSVs 416 and/or the like).

In the embodiments discussed above, the stacked semiconductor assemblies can be manufactured using a wafer-to-wafer bonding process and/or a chip-to-wafer bonding process. For example, the stacked semiconductor assemblies of FIG. 2A and FIG. 3 can be manufactured using wafer-to-wafer bonding processes. The stacked semiconductor assembly can also use a combination of both wafer-to-wafer and chip-to-wafer bonding processes. For example, the sub-assemblies of FIG. 4A can be manufactured using a wafer-to-wafer bonding process and the sub-assembly to sub-assembly bonding can be performed using chip-to-wafer bonding processes. However, the embodiments are not limited to any particular bonding process and any appropriate bonding process can be used. Wafer-to-wafer and chip-to-wafer bonding processes are known in the art and thus will not be discussed further.

As discussed above, unlike the related art fabrication process, because an end semiconductor die is flipped, the TSVs in the stacked semiconductor assembly can be tested as the assembly is being fabricated. If the TSVs in a semiconductor die fail, the partially-fabricated semiconductor assembly can be discarded before any more good dies are added to the assembly and/or before bonding the assembly to a semiconductor device. In addition, along with TSV integrity tests, functional tests of the semiconductor dies can be performed as the semiconductor assembly is being stacked. Further, “downgraded” semiconductor devices can be identified and salvaged in embodiments of the present disclose. For example, in a case where the TSVs are good but the functional circuit checks on a semiconductor die fail and/or in a case where the TSVs in the semiconductor die may be degraded but still good enough to “pass-though” signals, a “downgraded” semiconductor device that disables the faulty semiconductor die can still be assembled and sold. Accordingly, embodiments of the present disclosure increase the yield of semiconductor devices because failed semiconductor dies can be discarded during manufacturing or disabled after manufacturing.

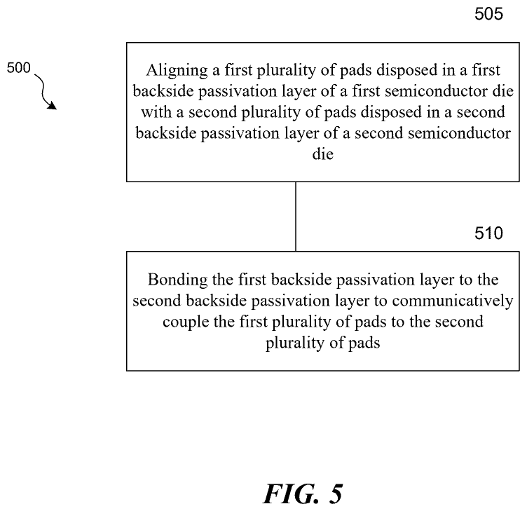

FIG. 5 is a flow diagram of a generalized process 500 for forming a stacked semiconductor assembly in accordance with some embodiments of the present disclosure. In step 505, the process 500 includes aligning a first plurality of pads disposed in a first backside passivation layer of a first semiconductor die with a second plurality of pads disposed in a second backside passivation layer of a second semiconductor die. As discussed above, the backside passivation layer 260b of semiconductor die 250 interfaces with backside passivation layer 220b of semiconductor die 210 such that the pads 263 in backside passivation layer 260b align with the pads 223 in the backside passivation layer 220b (see, e.g., FIG. 4A). In step 510, the process 500 includes bonding the first backside passivation layer to the second backside passivation layer to communicatively couple the first plurality of pads to the second plurality of pads. As discussed above, semiconductor die 250 can be bonded to semiconductor die 210 using, for example, hybrid bonding, solder bonding, etc. The process of bonding communicatively couples the pads 263 with the pads 223.

From the foregoing, it will be appreciated that specific embodiments of the technology have been described herein for purposes of illustration, but well-known structures and functions have not been shown or described in detail to avoid unnecessarily obscuring the description of the embodiments of the technology. To the extent any material incorporated herein by reference conflicts with the present disclosure, the present disclosure controls. Where the context permits, singular or plural terms may also include the plural or singular term, respectively. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded.

From the foregoing, it will also be appreciated that various modifications may be made without deviating from the disclosure or the technology. For example, one of ordinary skill in the art will understand that various components of the technology can be further divided into subcomponents, or that various components and functions of the technology may be combined and integrated. In addition, certain aspects of the technology described in the context of particular embodiments may also be combined or eliminated in other embodiments. Furthermore, although advantages associated with certain embodiments of the technology have been described in the context of those embodiments, other embodiments may also exhibit such advantages, and not all embodiments need necessarily exhibit such advantages to fall within the scope of the technology. Accordingly, the disclosure and associated technology can encompass other embodiments not expressly shown or described herein.

We claim:

1. A semiconductor device, comprising:
a first semiconductor die having a first backside passivation layer; and
a second semiconductor die having a second backside passivation layer,
wherein the first backside passivation layer interfaces to the second backside passivation layer to form a stacked semiconductor assembly and provides one or more communicative couplings between the first and second semiconductor dies.

2. The semiconductor device of claim 1, wherein the one or more communicative couplings are formed by pads disposed in the first and second backside passivation layers.

3. The semiconductor device of claim 1, wherein a layout arrangement of circuits in a first device layer of the first semiconductor die is a mirror image in comparison to a layout arrangement of circuits in a second device layer of the second first semiconductor die.

4. The semiconductor device of claim 1,
wherein the first semiconductor die comprises a first device layer comprising first built-in test circuits and a first substrate comprising first through-silicon vias (TSVs),
wherein the second semiconductor die comprises a second device layer comprising second built-in test circuits and a second substrate comprising second TSVs,
wherein the first and second built-in test circuits are configured to create a test signal path for testing the first and second TSVs, the test signal path created between a first test pad and a second test pad on a frontside passivation layer of the second semiconductor die, and
wherein the test signal path includes the first TSVs and the second TSVs.

5. The semiconductor device of claim 1, further comprising:
one or more third semiconductor dies having backside passivation layers,
wherein a backside passivation layer of a third semiconductor die of the one or more third semiconductor dies interfaces to a frontside passivation layer of the second semiconductor die or to a frontside passivation layer of another third semiconductor die of the one or more third semiconductor dies to provide one or more second communicative couplings between the respective semiconductor dies.

6. The semiconductor device of claim 5, wherein the first, second, and third semiconductor dies are memory dies, and
wherein the first semiconductor die is an end die of the stacked semiconductor assembly with no adjacent memory dies on one side.

7. The semiconductor device of claim 1, further comprising:
one or more third semiconductor dies having third backside passivation layers; and
one or more fourth semiconductor dies having fourth backside passivation layers,
wherein the third backside passivation layers interface to the respective fourth backside passivation layers to form one or more second stacked semiconductor assemblies and provide one or more second communicative couplings between the respective third and fourth semiconductor dies, and
wherein a frontside passivation layer of a third semiconductor die in the one or more second stacked semiconductor assemblies interfaces with a frontside passivation layer of the second semiconductor die or with a frontside passivation layer of another third semiconductor die of the one or more second stacked assemblies to provide one or more third communicative couplings between the respective semiconductor dies.

8. The semiconductor device of claim 1, wherein the interface comprises hybrid bonding.

9. The semiconductor device of claim 1, wherein the interface comprises solder bonding.

10. The semiconductor device of claim 1, wherein the stacked semiconductor assembly is bonded to an interface die in the semiconductor device, and wherein the semiconductor device is a system-in-package (SiP).

11. A method of forming a stacked semiconductor assembly, the method comprising:
aligning a first plurality of pads disposed in a first backside passivation layer of a first semiconductor die with a second plurality of pads disposed in a second backside passivation layer of a second semiconductor die; and
bonding the first backside passivation layer to the second backside passivation layer to communicatively couple the first plurality of pads to the second plurality of pads.

12. The method of claim 11, wherein a layout arrangement of circuits in a first device layer of the first semiconductor die is a mirror image in comparison to a layout arrangement of circuits in a second device layer of second first semiconductor die.

13. The method of claim 11, further comprising:
creating a test signal path for testing through-silicon vias (TSVs) in the stacked semiconductor assembly, the test signal path created between a first test pad and a second test pad on a frontside passivation layer of the second semiconductor die, the test signal path including first TSVs formed in the first semiconductor die and second TSVs formed in the second semiconductor die.

14. The method of claim 11, further comprising:
aligning a third plurality of pads disposed in a third backside passivation layer of a third semiconductor die with a fourth plurality of pads disposed in a frontside passivation layer of the second semiconductor die; and
bonding the third backside passivation layer to the frontside passivation layer to communicatively couple the third plurality of pads to the fourth plurality of pads.

15. The method of claim 14, wherein the first, second, and third semiconductor dies are memory dies, and
wherein the first semiconductor die is an end die of the stacked semiconductor assembly with no adjacent memory dies on one side.

16. The method of claim 11, further comprising:
aligning a third plurality of pads disposed in a third backside passivation layer of a third semiconductor die with a fourth plurality of pads disposed in a fourth backside passivation layer of a fourth semiconductor die;
bonding the third backside passivation layer to the fourth backside passivation layer to communicatively couple the third plurality of pads to the fourth plurality of pads;
aligning a fifth plurality of pads disposed in a first frontside passivation layer of the second semiconductor die with a sixth plurality of pads disposed in a second frontside passivation layer of the third semiconductor die; and
bonding the first frontside passivation layer to the second frontside passivation layer to communicatively couple the fifth plurality of pads to the sixth plurality of pads.

17. The method of claim 11, wherein the bonding comprises hybrid bonding.

18. The method of claim 11, wherein the bonding comprises solder bonding.

19. A method of forming a semiconductor device, the method comprising:
aligning a first plurality of pads disposed in a first backside passivation layer of a first semiconductor die with a second plurality of pads disposed in a second backside passivation layer of a second semiconductor die;
bonding the first backside passivation layer to the second backside passivation layer to communicatively couple the first plurality of pads to the second plurality of pads to form a stacked semiconductor assembly; and
bonding the stacked semiconductor assembly to an interface die of the semiconductor device.

20. The method of claim 19, wherein the first and second semiconductor dies are memory dies and the semiconductor device is a system-in-package (SiP).
